(19) United States
(12) Patent Application Publication
(10) Pub. No.: US 2017/0222012 A1
(43) Pub. Date: Aug. 3, 2017

(54) SEMICONDUCTOR DEVICE AND MANUFACTURING METHOD THEREFOR

(71) Applicant: CSMC TECHNOLOGIES FAB1 CO., LTD., Wuxi New District (CN)

(72) Inventors: Long HAO, Wuxi New District, Jiangsu (CN); Yan JIN, Wuxi New District, Jiangsu (CN); Wei LI, Wuxi New District, Jiangsu (CN)

(21) Appl. No.: 15/328,623

(22) PCT Filed: Sep. 2, 2015
(86) PCT No.: PCT/CN2015/088836

§ 371 Date: Jan. 24, 2017

(30) Foreign Application Priority Data
Sep. 2, 2014 (CN) 201410444255.7

(51) Int. Cl. H01L 29/49; H01L 21/28; H01L 29/66

(52) U.S. Cl. CPC H01L 29/4916; H01L 29/66477; H01L 21/28035

(57) ABSTRACT

A manufacturing method for a semiconductor device is provided. The method comprises: providing a semiconductor substrate (200); sequentially forming an oxide layer (201) and a silicon nitride layer (202) on the semiconductor substrate (200); annealing the silicon nitride layer (202), and then etching an active region (401) by using the silicon nitride layer (202) as a mask, so as to form in the semiconductor substrate (200) a trench (203) for filling an isolation material, wherein the active region (401) comprises a gate region (403) and a source region (404) and a drain region (405) that are respectively located on two sides of the gate region (403), and the gate region (403) comprises a body part connected to the source region (404) and the drain region (405) and a protruding part (406) that protrudes and extends from the body part to the trench; etching-back the silicon nitride layer (202) and forming a lining oxide layer (201) on the sidewall and the bottom of the trench; depositing an isolation material layer (205) to fill the trench; grinding the isolation material layer (205) until the top of the silicon nitride layer (202) is exposed; and etching to remove the silicon nitride layer (202).

### FIELD OF THE INVENTION

The present disclosure relates to semiconductors, and more particularly relates to a semiconductor device and a method of manufacturing the semiconductor device.

### BACKGROUND OF THE INVENTION

Due to a development of the integrated circuit, a requirement of the device is higher and higher, an influence to the circuit by the bimodal effect emerges.

The bimodal effect indicates that two greatest peak values emerge in the trans-conductance when detecting the threshold voltage of the device. Due to the existence of two peak values, the threshold voltage curve fluctuates, thus error occurs when calculating the threshold voltage. Under normal conditions, the reason of the bimodal effect is the fringe effect of the device. Because there is a difference between a thickness of the gate oxide layer on the device edge and a thickness of the gate oxide layer on the master device region of the centre of the device, and the difference can be enlarged according to an increased of the thickness of the gate oxide layer, which is equivalent to two parasitic devices 101 existing on the device edge, there is a difference between the threshold voltage of the two parasitic devices and the threshold voltage of the master device region 102 of the centre of the device. Above two differences are the main sources of the bimodal effect.

The bimodal effect may lead to an output error of the circuit, and results in an invalid of the terminal, the circuit cannot work normally, and a reliability of the whole circuit is influenced

### SUMMARY

Therefore, it is necessary to provide a semiconductor device without a bimodal effect and a method of manufacturing the semiconductor device, in order to improve a reliability of the circuit.

A method of manufacturing a semiconductor device includes: providing a semiconductor substrate;
forming an oxide layer and a silicon nitride layer on the semiconductor substrate sequentially;
annealing the silicon nitride layer, and etching an active region by using the silicon nitride layer as a mask, thereby forming a trench for filling an isolation material in the semiconductor substrate;
etching-back the silicon nitride layer and forming a lining oxide layer on a sidewall and a bottom of the trench;
depositing the isolation material layer to fill the trench;
grinding the isolation material layer until a top of the silicon nitride layer is exposed; and etching to remove the silicon nitride layer;
wherein the active region comprises a gate region, and a source region and a drain region that are located on opposite sides of the gate region respectively, and the gate region comprises a body portion connected to the source region and the drain region, and a protruding portion protruding from the body portion towards the trench.

Preferably, the semiconductor device comprises a gate partially covering the active region, a vertical distance between a surface of the protruding portion facing the trench and a surface of the source region and the drain region facing the trench ranges from 0.05 micrometers to 0.2 micrometers

Preferably, a projection of the protruding portion on a horizontal plane is a rectangle

Preferably, the protruding portion comprises an extension portion extending towards the source region and the drain region, an extension length of the extension potion ranges from 0 to 0.2 micrometers.

Preferably, a projection of the extension portion on a horizontal plane is a square.

A semiconductor device, includes: an active region and a gate partially covering the active region, wherein the active region comprises a gate region beneath the gate, and a source region and a drain region located on opposite sides of the gate region respectively, the active region is provided with a top surface beneath the gate and a side surface perpendicular to the top surface, the gate region comprises a protruding portion protruding along a direction perpendicular to the side surface

Preferably, a vertical distance between a side surface of the protruding portion and a side surface of the source region and the drain region ranges from 0.05 micrometers to 0.2 micrometers

Preferably, a top surface of the protruding portion is a rectangle

Preferably, the protruding portion comprises an extension portion extending towards the source region and the drain region, an extension length of the extension potion ranges from 0 to 0.2 micrometers.

Preferably, a top surface of the extension portion is a square.

Preferably, the gate is made of a polycrystalline silicon.

According to the present disclosure, the bimodal effect of the device can be completely eliminated without adding a new step and increasing the manufacturing cost, and it cannot be limited to the edge morphology of the active region, a reliability of device is improved accordingly.

### BRIEF DESCRIPTION OF THE DRAWINGS

The following drawings form part of the specification and are included to further demonstrate certain embodiments or various aspects of the invention, wherein:

FIG. 1 is a perspective view of a semiconductor device having a standard construction which may generate a bimodal effect.

FIG. 2 is a top view of an active region of the semiconductor device of FIG. 1, when in a manufacturing process.

FIG. 3 is a front view of a cut out portion, taken along line A-A′ and B-B′ of the active region of FIG. 2;

FIG. 4A through FIG. 4F are cross-sectional views of devices, respectively obtained by steps of a method of manufacturing a conventional semiconductor device.

FIG. 5 is a flow chart of a method of manufacturing a semiconductor device according to an embodiment;

FIG. 6 is a perspective view of a semiconductor device according to an embodiment;

FIG. 7 is a top view of an active region of the semiconductor device of FIG. 6, when in a manufacturing process;

FIG. 8 is a front view of a cut out portion, taken along line C-C′ and D-D′ of the active region of FIG. 7; and

FIG. 9 is a comparison view of the bimodal effects between the semiconductor device of the present disclosure and the semiconductor device having a standard construction.

### DETAILED DESCRIPTION OF THE EMBODIMENTS

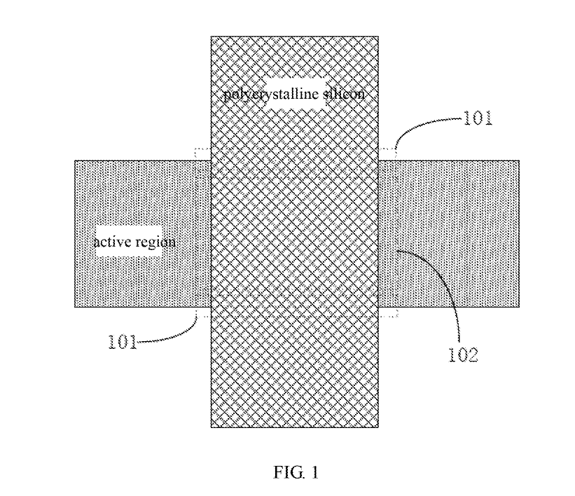

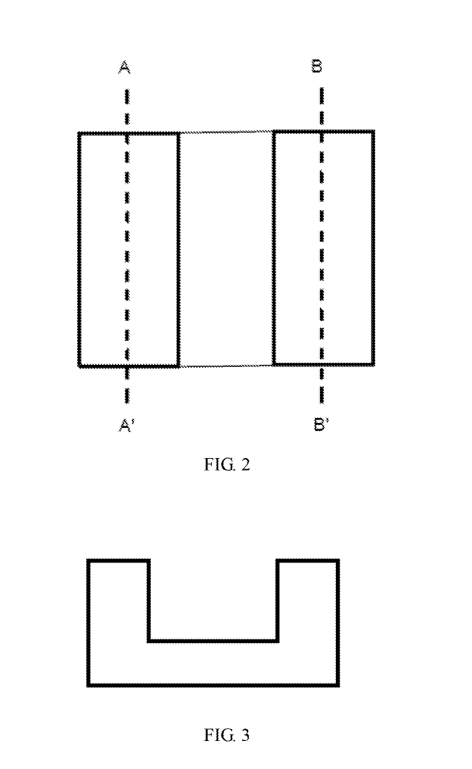

As shown in FIG. 1 through FIG. 3, the conventional semiconductor device can generate a bimodal effect easily. In order to inhibit an emergent of the bimodal effect of the device, the prior method is to keep a thickness of the gate oxide layer on the device edge and a thickness of the gate oxide layer on the master device region of the centre of the device the same or reduce a difference between the two thicknesses through various technical solutions.

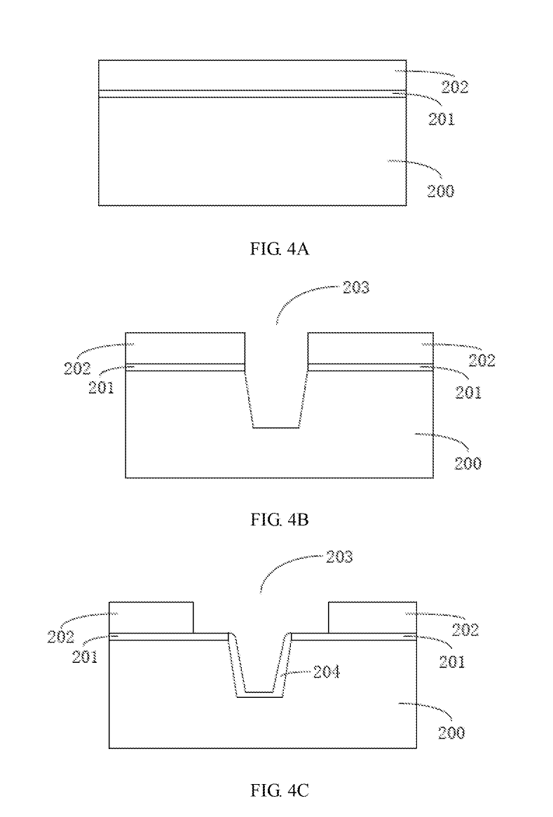

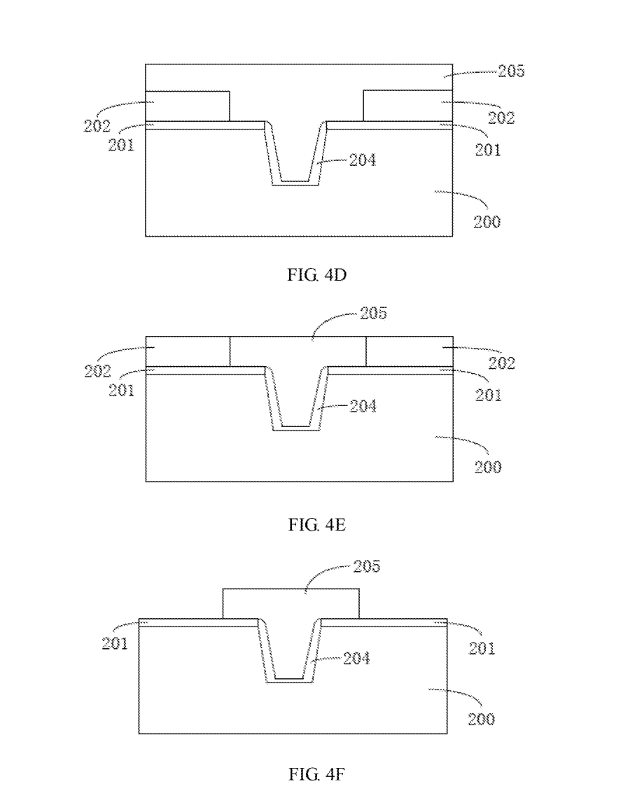

Such technologies mainly include two methods: one is to adjust the process of the active region of the device, and enables the corner portions of the active region to be more smooth, and then enables a growth of the gate oxide layer to be more even, thereby reducing a difference between the thickness of the gate oxide layer on the device edge and the thickness of the gate oxide layer on the master device region of the centre of the device. For example, first, as shown in FIG. 4A, a semiconductor substrate 200 is provided, the constitute material of the semiconductor substrate 200 can adopt monocrystalline silicon, monocrystalline silicon doped with impurities, a silicon on insulator (SOI), and so on, a thin oxide layer 201 and a thin silicon nitride layer 202 are formed on the semiconductor substrate 200 sequentially, when the thin oxide layer 201 serves a buffer layer, a stress between the silicon nitride layer 202 and the semiconductor substrate 200 can be released; and then, as shown in FIG. 4B, after the silicon nitride layer 202 is annealed, an active region is etched by using the silicon nitride layer 202 as a mask, thereby forming a trench 203 in the semiconductor substrate 200 for filling an isolation material (serves as a field oxide); and then, as shown in FIG. 4C, the silicon nitride layer 202 is etched-back and a lining oxide layer 204 is formed on a sidewall and a bottom of the trench 203; and then, as shown in FIG. 4D, the isolation material layer 205 is deposited to fill the trench 203; and then, as shown in FIG. 4E, the isolation material layer 205 is grinded until a top of the silicon nitride layer 202 is exposed; and finally, the silicon nitride layer 202 is etched and removed. In the example, by etching-back the silicon nitride layer 202, after the lining oxide layer 204 is formed on the sidewall and the bottom of the trench 203, the corner portions of the active region are more smooth, when growing a gate oxide layer on the semiconductor 200 subsequently, a difference between the thickness of the gate oxide layer on the device edge and the thickness of the gate oxide layer on the master device region of the centre of the device are reduced.

Another one is to increase a height of a step of the active region of the field oxide of the device, to prevent an expose of the corners located on the active region when growing the gate oxide layer. Actually, the field oxide is employed to remedy the deficiency of an incomplete growth of the gate oxide layer on the corners of the active region, thereby reducing the difference between the thickness of the gate oxide layer on the device edge and the thickness of the gate oxide layer on the master device region of the centre of the device

However, both aforementioned methods do not and cannot eliminate the edge effect of the device completely, and thus cannot fundamentally eliminate the bimodal effect. Because no matter how to implement, they cannot provide a consistent between the device edge and the master device region, which is determined by the structure of the device. If only the device works, there is current on the device edge, and two parasitic devices exist, and the two parasitic device cannot be consistent with the master device region.

Therefore, the present disclosure provides a semiconductor device without a bimodal effect and a method of manufacturing the semiconductor device.

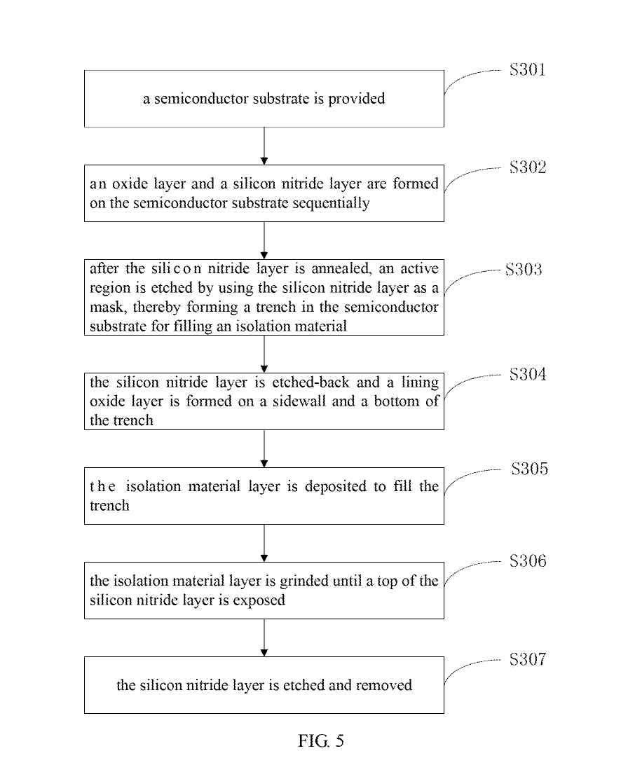

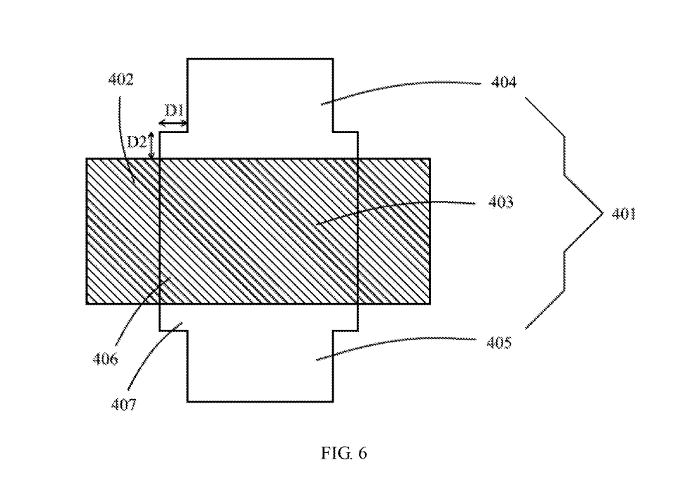

As shown in FIG. 5, a method of manufacturing a semiconductor device includes steps as follow:

In step S301, a semiconductor substrate is provided.

In step S302, an oxide layer and a silicon nitride layer are formed on the semiconductor substrate sequentially;

In step S303, after the silicon nitride layer is annealed, an active region is etched by using the silicon nitride layer as a mask, thereby forming a trench in the semiconductor substrate for filling an isolation material; the active region includes a gate region, and a source region and a drain region that are located on opposite sides of the gate region respectively, and the gate region includes a body portion connected to the source region and the drain region, and a protruding portion protruding from the body portion towards the trench.

In step S304, the silicon nitride layer is etched-back and a lining oxide layer is formed on a sidewall and a bottom of the trench;

In step S305, the isolation material layer is deposited to fill the trench;

In step S306, the isolation material layer is grinded until a top of the silicon nitride layer is exposed;

In step S307, the silicon nitride layer is etched and removed.

In one embodiment, the semiconductor device includes a gate partially covering the active region, a vertical distance between a surface of the protruding portion facing the trench and a surface of the source region and the drain region facing the trench ranges from 0.05 micrometers to 0.2 micrometers, and preferably the vertical distance is 0.1 micrometers. In the embodiment, a projection of the protruding portion 406 on the horizontal plane is a rectangle. In other embodiments, a projection of the protruding portion 406 on the horizontal plane has an arc shape.

In one embodiment, the protruding portion includes an extension portion extending towards the source region and the drain region, an extension length of the extension potion ranges from 0 to 0.2 micrometers, and preferably, the extension length is 0.1 micrometers. In the embodiment, a projection of the extension portion 407 on the horizontal plane is a square, the side length of the square is 0.1 micrometers. In other embodiment, the extension portion 407 is a rectangle.

In the method of manufacturing a semiconductor device according to the present disclosure, the bimodal effect of the device can be completely eliminated without adding a new step and increasing the manufacturing cost, and it cannot be limited to the edge morphology of the active region, a reliability of device is improved accordingly.

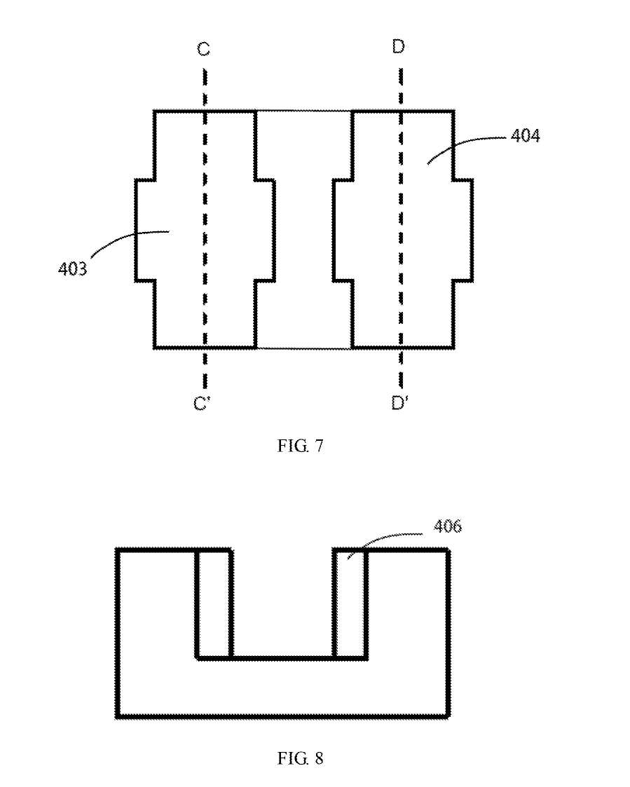

FIG. 6 is a perspective view of a semiconductor device according to an embodiment; FIG. 7 is a top view of an active region of the semiconductor device of FIG. 6; FIG. 8 is a front view of a cut out portion, taken along line C-C′ and D-D′ of the active region of FIG. 7. As shown in FIG. 6 through FIG. 8, an active region 401 and a gate 402 partially covering the active region 401 are included. The active region 401 includes a gate region 403 beneath the gate 402, and a source region 404 and a drain region 405 located on opposite sides of the gate region 403. The active region 401 is provided with a top surface beneath the gate 402 and a side surface perpendicular to the top surface. The gate region 403 includes a protruding portion 406 protruding along a direction perpendicular to the side surface.

In one embodiment, a vertical distance D1 between a side surface of the protruding portion 406 and a side surface of the source region 404 and the drain region 405 ranges from 0.05 micrometers to 0.2 micrometers. A top surface of the protruding portion 406 is a rectangle. In other embodiments, the top surface of the protruding portion 406 can also has an arc shape.

In one embodiment, the protruding portion 406 includes an extension portion extending toward the source region 404 and the drain region 405, an extension length D2 of the extension potion 407 ranges from 0 to 0.2 micrometers, and preferably, the extension length is 0.1 micrometers. In the embodiment, a top surface of the extension portion 407 is a square, the side length of the square is 0.1 micrometers. In other embodiment, the top surface of the extension portion 407 is a rectangle.

In other embodiment, the gate 402 is made of a polycrystalline silicon.

By virtue of providing the protruding portion 406, on the basis of the standard active region, a width of the active region 401 on the gate region 403 beneath the gate 402 is increased, causing the active region to be distal from the conductive channel, such that the parasitic device is eliminated, thus an edge effect of the device is fundamentally solved, and the bimodal effect of the device is completely eliminated.

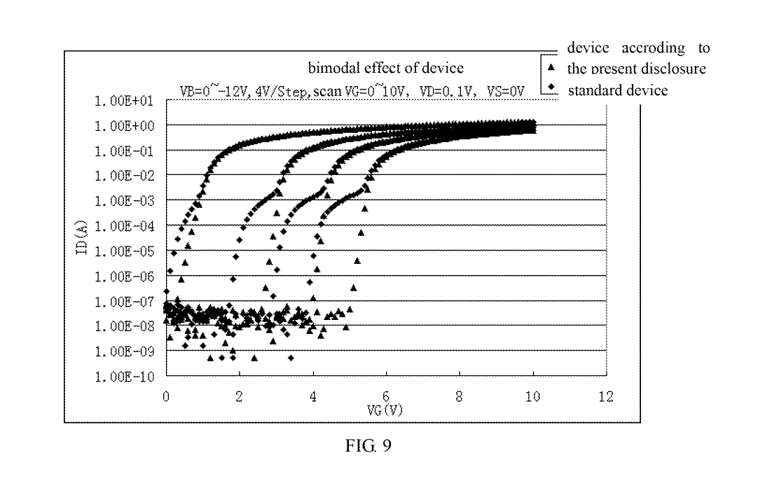

As shown in FIG. 9, at the same edge morphology of the active region, the semiconductor device of the present disclosure does not have a bimodal effect at all, as the right side curve in the two pairs curves in FIG. 9, and the bimodal effect in the device of the standard structure is very serious, as the left side curve in the two pairs curves in FIG. 9.

In the semiconductor device according to the present disclosure, the bimodal effect of the device can be completely eliminated without adding a new step and increasing the manufacturing cost, and it cannot be limited to the edge morphology of the active region, a reliability of device is improved accordingly.

The invention is illustrated with reference to aforementioned embodiments, it should be understand that, above embodiments are merely provided for example and illustration, and should not be deemed as limitations to the scope of the present invention. It should be noted that variations and improvements will become apparent to those skilled in the art to which the present invention pertains without departing from its spirit and scope. Therefore, the scope of the present invention is defined by the appended claims and equivalents.

What is claimed is:

1. A method of manufacturing a semiconductor device, comprising:
providing a semiconductor substrate;
forming an oxide layer and a silicon nitride layer on the semiconductor substrate sequentially;
annealing the silicon nitride layer, and etching an active region by using the silicon nitride layer as a mask, thereby forming a trench in the semiconductor substrate for filling an isolation material, wherein the active region comprises a gate region, and a source region and a drain region that are located on opposite sides of the gate region, respectively, and the gate region comprises a body portion connected to the source region and the drain region, and a protruding portion protruding from the body portion towards the trench;
etching-back the silicon nitride layer and forming a lining oxide layer on a sidewall and a bottom of the trench;
depositing the isolation material layer to fill the trench;
grinding the isolation material layer until a top of the silicon nitride layer is exposed; and
etching to remove the silicon nitride layer.

2. The method according to claim 1, wherein the semiconductor device comprises a gate partially covering the active region, a vertical distance between a surface of the protruding portion facing the trench and a surface of the source region and the drain region facing the trench ranges from 0.05 micrometers to 0.2 micrometers.

3. The method according to claim 2, wherein a projection of the protruding portion on a horizontal plane is a rectangle.

4. The method according to claim 2, wherein the protruding portion comprises an extension portion extending towards the source region and the drain region, an extension length of the extension potion ranges from 0 to 0.2 micrometers.

5. The method according to claim 4, wherein a projection of the extension portion on a horizontal plane is a square.

6. A semiconductor device, comprising: an active region and a gate partially covering the active region, wherein the active region comprises a gate region beneath the gate and a source region and a drain region located on opposite sides of the gate region, the active region is provided with a top surface beneath the gate and a side surface perpendicular to the top surface, the gate region comprises a protruding portion protruding along a direction perpendicular to the side surface.

7. The semiconductor according to claim 6, wherein a vertical distance between a side surface of the protruding portion and a side surface of the source region and the drain region ranges from 0.05 micrometers to 0.2 micrometers.

8. The semiconductor according to claim 7, wherein a top surface of the protruding portion is a rectangle.

9. The semiconductor according to claim 7, wherein the protruding portion comprises an extension portion extending towards the source region and the drain region, an extension length of the extension potion ranges from 0 to 0.2 micrometers.

10. The semiconductor according to claim 9, wherein a top surface of the extension portion is a square.

11. The semiconductor according to claim 6, wherein the gate is made of polycrystalline silicon.
